(19) United States
(12) Patent Application Publication
(10) Pub. No.: US 2024/0260419 A1
(43) Pub. Date: Aug. 1, 2024

(54) ORGANIC LIGHT-EMITTING DIODE DISPLAY DEVICE AND METHOD OF MANUFACTURING THE SAME

(71) Applicant: LG Display Co., Ltd., Seoul (KR)

(72) Inventors: Ho-Jin KIM, Paju-si (KR); Bong-Choon KWAK, Paju-si (KR); Ji-Yeon PARK, Paju-si (KR)

(73) Assignee: LG Display Co., Ltd., Seoul (KR)

(21) Appl. No.: 18/514,780

(22) Filed: Nov. 20, 2023

(30) Foreign Application Priority Data
Jan. 31, 2023 (KR) 10-2023-0013239

(51) Int. Cl. H10K 59/80; H10K 59/12; H10K 59/122

(52) U.S. Cl. CPC H10K 59/878; H10K 59/1201; H10K 59/122

(57) ABSTRACT

An organic light-emitting diode display device can include a plurality of sub-pixels disposed on a substrate, at least one transistor disposed at each of the plurality sub-pixels over the substrate, a first insulation layer disposed over the at least one transistor, and a light-emitting diode disposed at each of the plurality of sub-pixels over the first insulation layer. Further, the light-emitting diode includes a first electrode, a light-emitting layer, and a second electrode. Also, each of the plurality of sub-pixels includes a contact area and an emission area, the light-emitting diode is electrically connected to the at least one transistor in the contact area. The first insulation layer includes a recessed portion in the contact area.

### CROSS-REFERENCE TO RELATED APPLICATION

The present application claims priority to Korean Patent Application No. 10-2023-0013239 filed in the Republic of Korea, on Jan. 31, 2023, the entirety of which is hereby expressly incorporated by reference into the present application.

### BACKGROUND

### Field of the Disclosure

The present disclosure relates to a display device, and more particularly, to an organic light-emitting diode display device with improved color reproducibility and a method of manufacturing the same.

### Discussion of the Related Art

As the information society progresses, a demand for different types of display devices increases. As such, flat panel display devices (FPD) such as liquid crystal display devices (LCD) and organic light-emitting diode display devices (OLED) have been developed and applied to various fields.

Among the flat panel display devices, organic light-emitting diode display devices, which are also referred to as organic electroluminescent display devices, emit light due to the radiative recombination of an exciton. The exciton is formed from an electron and a hole by injecting charges into a light-emitting layer between a cathode for injecting electrons and an anode for injecting holes in a light-emitting diode.

The organic light-emitting diode display device can be formed over a flexible substrate, such as plastic, and offers various advantages and improved properties. For instance, because it is self-luminous, the organic light-emitting diode display device has an excellent contrast ratio and an ultra-thin thickness, and has a response time of several microseconds. As such, there are advantages in displaying moving images and videos without delays using the organic light-emitting diode display device.

Additionally, the organic light-emitting diode display device has a wide viewing angle and is stable under low temperatures. Further, since the organic light-emitting diode display device is generally driven by a low voltage of direct current (DC) (e.g., 5V to 15V), it can be easy to design and manufacture the driving circuits of the organic light-emitting diode display device.

Recently, as the organic light-emitting diode display device is applied to various fields, a display device having high resolution is needed. In order to implement such a high resolution, more sub-pixels can be provided within the same area. Accordingly, the area of each sub-pixel can be reduced, and a distance between adjacent sub-pixels can also be decreased.

However, this decrease in the distance between adjacent sub-pixels can cause a lateral leakage current between adjacent sub-pixels. According to this configuration, unwanted sub-pixels can emit light, which can lower the color reproducibility of the display device and increase power consumption.

### SUMMARY OF THE DISCLOSURE

Accordingly, the present disclosure is directed to an organic light-emitting diode display device and a method of manufacturing the same that substantially obviate one or more of the limitations and disadvantages described above and associated with the background art.

More specifically, an object of the present disclosure is to provide an organic light-emitting diode display device capable of minimizing a lateral leakage current between adjacent sub-pixels and a method of manufacturing the same.

Another object of the present disclosure is to provide an organic light-emitting diode display device capable of increasing light efficiency and a method of manufacturing the same.

Additional features and aspects will be set forth in the description that follows, and in part will be apparent from the description, or can be learned by practice of the present disclosure provided herein. Other features and aspects of the inventive concepts can be realized and attained by the structure particularly pointed out in the written description, or derivable therefrom, and the claims hereof as well as the appended drawings.

To achieve these and other aspects of the present disclosure, as embodied and broadly described herein, an organic light-emitting diode display device includes a substrate providing with a plurality of sub-pixels; at least one transistor at each of the plurality sub-pixels over the substrate; a first insulation layer over the at least one transistor; and a light-emitting diode at each of the plurality of sub-pixels over the first insulation layer, and including a first electrode, a light-emitting layer, and a second electrode, in which each of the plurality of sub-pixels includes a contact area and an emission area, in which the light-emitting diode is electrically connected to the at least one transistor in the contact area, and in which the first insulation layer includes a recessed portion in the contact area.

In another aspect, a method of manufacturing an organic light-emitting diode display device includes forming at least one transistor at each of a plurality of sub-pixels over a substrate; forming at least one insulation layer over the at least one transistor and having a recessed portion; and forming a light-emitting diode at each of the plurality of sub-pixels over the at least one insulation layer and including a first electrode, a light-emitting layer, and a second electrode, in which each of the plurality of sub-pixels includes a contact area and an emission area, in which the light-emitting diode is electrically connected to the at least one transistor in the contact area, and in which the recessed portion is disposed in the contact area.

It is to be understood that both the foregoing general description and the following detailed description are examples and are intended to provide further explanation of the inventive concepts as claimed.

### BRIEF DESCRIPTION OF THE DRAWINGS

The accompanying drawings, which are included to provide a further understanding of the present disclosure and which are incorporated in and constitute a part of this application, illustrate aspects of the disclosure and together with the description serve to explain various principles of the present disclosure.

In the drawings:

FIG. 1 is a plan view schematically illustrating an organic light-emitting diode display device according to an embodiment of the present disclosure;

FIG. 2 is a schematic cross-sectional view taken along the line I-I′ of FIG. 1 according to an embodiment of the present disclosure;

FIG. 3 is a schematic cross-sectional view taken along the line II-II′, the line III-III′, and the line IV-IV′ of FIG. 1 according to an embodiment of the present disclosure;

FIGS. 4A to 4N are schematic cross-sectional views of an organic light-emitting diode display device corresponding to the line I-I′ of FIG. 1 in steps of manufacturing the organic light-emitting diode display device according to an embodiment of the present disclosure; and

FIGS. 5A to 5N are schematic cross-sectional views of an organic light-emitting diode display device corresponding to the line II-II′, the line III-III′, and the line IV-IV′ of FIG. 1 in steps of manufacturing the organic light-emitting diode display device according to an embodiment of the present disclosure.

### DETAILED DESCRIPTION OF THE EMBODIMENTS

Reference will now be made in detail to embodiments, examples of which are illustrated in the accompanying drawings. The same or like reference numbers can be used throughout the drawings to refer to the same or like parts. The features of various embodiments of the present disclosure can be partially or entirely coupled to or combined with each other and can be interlocked and operated in technically various ways, and the embodiments can be carried out independently of or in association with each other.

Hereinafter, an organic light-emitting diode display device and a method of manufacturing the same according to embodiments of the present disclosure will be described in detail with reference to the accompanying drawings.

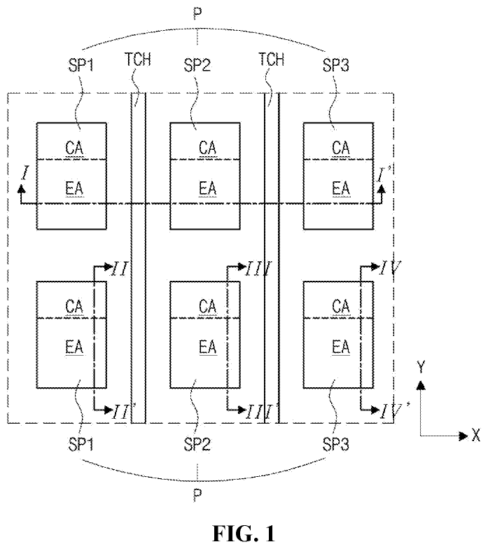

FIG. 1 is a plan view schematically illustrating an organic light-emitting diode display device according to an embodiment of the present disclosure.

In FIG. 1, the organic light-emitting diode display device according to an embodiment of the present disclosure can include a plurality of pixels P arranged in a matrix form along a first direction, which is an X direction, and a second direction, which is a Y direction. Each pixel P can include a plurality of sub-pixels SP1, SP2, and SP3. Although only two pixels P arranged along the second direction are shown in FIG. 1, other pixels P having the same configuration can also be arranged along the first direction.

One pixel P can include first, second, and third sub-pixels SP1, SP2, and SP3. For example, the first, second, and third sub-pixels SP1, SP2, and SP3 can be red, green, and blue sub-pixels, respectively. However, embodiments of the present disclosure are not limited thereto. Alternatively, the number of sub-pixels included in one pixel P can vary. For example, one pixel P can include red, green, blue, and white sub-pixels.

At least one thin film transistor and a light-emitting diode can be provided at each of the first, second, and third sub-pixels SP1, SP2, and SP3.

Meanwhile, each of the first, second, and third sub-pixels SP1, SP2, and SP3 can include an emission area EA and a contact area CA. The light-emitting diode can be provided in the emission area EA and electrically connected to the at least one transistor in the contact area CA.

A trench TCH can be provided between two sub-pixels SP1, SP2, and SP3 adjacent to each other along the first direction. The trench TCH can extend along the second direction. For example, a plurality of trenches TCH can be arranged between columns of sub-pixels.

The trench TCH may not be provided between two sub-pixels adjacent to each other along the second direction, that is, between two first sub-pixels SP1, between two second sub-pixels SP2, and between two third sub-pixels SP3. However, embodiments of the present disclosure are not limited thereto. Alternatively, the trench TCH can be provided between two sub-pixels SP1, SP2, and SP3 adjacent to each other along the second direction. For example, a plurality of trenches TCH can be arranged between rows of sub-pixels. Also, according to an embodiment, the trench TCH can completely surround a perimeter of each sub-pixel (e.g., in a grid or lattice configuration), but embodiments are not limited thereto.

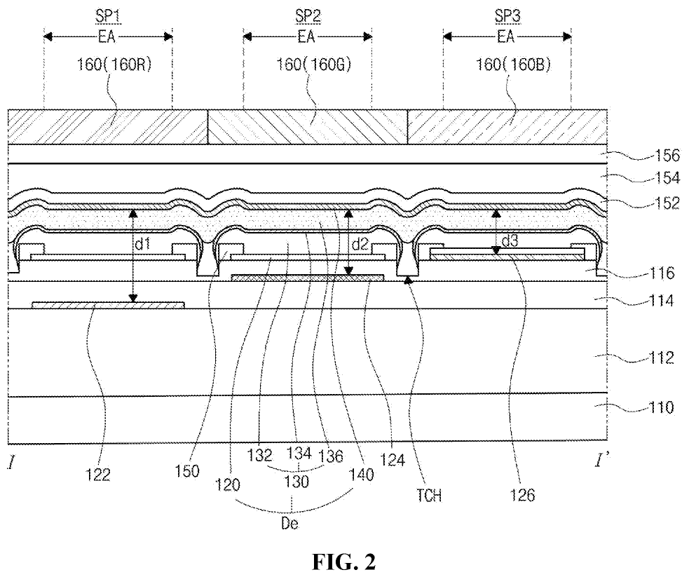

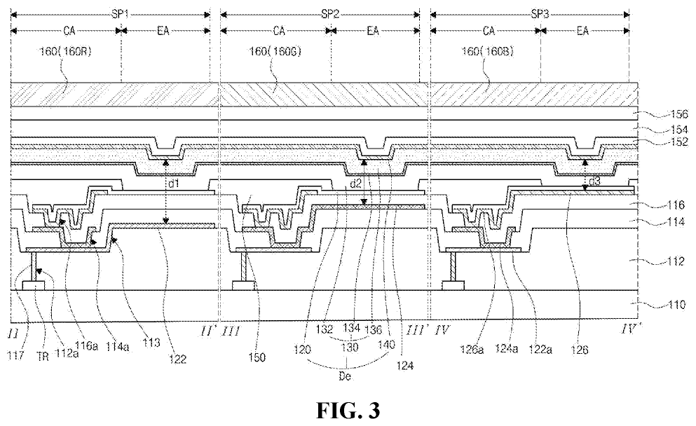

A cross-sectional structure of the organic light-emitting diode display device according to the embodiment of the present disclosure will be described with reference to FIG. 2 and FIG. 3.

FIG. 2 and FIG. 3 are schematic cross-sectional views of an organic light-emitting diode display device according to an embodiment of the present disclosure. FIG. 2 shows a cross-section taken along the line I-I′ of FIG. 1, and FIG. 3 shows a cross-section taken along the line II-II′, the line III-III′, and the line IV-IV′ of FIG. 1. Here, the organic light-emitting diode display device will be described as an example of a top emission type.

In FIG. 2 and FIG. 3, the organic light-emitting diode display device of an embodiment of the present disclosure can include a plurality of sub-pixels, e.g., first, second, and third sub-pixels SP1, SP2, and SP3. Each of the first, second, and third sub-pixels SP1, SP2, and SP3 can include a transistor TR and a light-emitting diode De.

Specifically, the transistor TR can be disposed in each of the first, second, and third sub-pixels SP1, SP2, and SP3 over a substrate 110. The first, second, and third sub-pixels can constitute one pixel P.

Here, the substrate 110 can be formed of a semiconductor material. For example, the substrate 110 can be a wafer formed of single crystal silicon. However, embodiments of the present disclosure are not limited thereto. Alternatively, the substrate 110 can be formed of an insulating material, such as glass or plastic.

The transistor TR can be a metal-oxide-semiconductor field effect transistor (MOSFET). However, the embodiments of the present disclosure are not limited thereto. Alternatively, the transistor TR can be a thin film transistor TFT.

The transistor TR can be a driving transistor connected to the light-emitting diode De. In addition, at least one transistor, at least one signal line, and at least one electrode, which can be connected to the driving transistor, can be further provided over the substrate 110.

For example, a switching transistor, a sensing transistor, a storage capacitor, a gate line, a data line, a power line, a sensing line and/or a reference line can be further provided over the substrate 110.

The switching transistor can be connected to the gate line, the data line, and the driving transistor and can be switched according to a gate signal of the gate line to thereby transmit a data signal of the data line to the driving transistor.

The driving transistor can be connected to the switching transistor, the power line, and the light-emitting diode De and can be switched according to the data signal transmitted from the switching transistor to thereby transmit a current according to a high potential voltage of the power line to the light-emitting diode De.

The sensing transistor can be connected to the driving transistor, the sensing line, and the reference line and can be switched according to a sensing signal of the sensing line to thereby transmit a reference voltage of the reference line to the driving transistor or detect a voltage of the driving transistor.

The storage capacitor can be connected to the switching transistor and the driving transistor and can serve to maintain the data signal transmitted from the switching transistor for one frame.

The driving transistor, the switching transistor, the sensing transistor, and the storage capacitor can be disposed in the contact area CA and/or the emission area EA. Also, according to another embodiment, the transistor TR can be disposed under or overlapping with the emission area EA (e.g., to save space), but embodiments are not limited thereto.

Next, a first insulation layer 112 can be provided over the transistor TR. The first insulation layer 112 can be disposed over a substantially entire surface of the substrate 110. The first insulation layer 112 can have a via hole 112a exposing the transistor TR of each sub-pixel SP1, SP2, and SP3. The via hole 112a can be located in the contact area CA.

In addition, the first insulation layer 112 can have a recessed portion 113 in the contact area CA of each sub-pixel SP1, SP2, and SP3. The recessed portion 113 can overlap with the via hole 112a and have a larger width and a larger size than the via hole 112a. For example, the via hole 112a can be in a bottom surface of the recessed portion 113.

The first insulation layer 112 can be formed as a single layer or multiple layers. For example, the first insulation layer 112 can be formed of an inorganic insulating material such as silicon oxide (SiOx) or silicon nitride (SiNx). However, embodiments of the present disclosure are not limited thereto. Alternatively, the first insulation layer 112 can be formed of an organic insulating material such as an acrylic resin, epoxy resin, phenol resin, polyamide resin, or polyimide resin.

A first contact electrode 122a of a metal material can be disposed in each of the first, second, and third sub-pixels SP1, SP2, and SP3 over the first insulation layer 112. The first contact electrode 122a can be located in the contact area CA. Here, the first contact electrode 122a can be placed in the recessed portion 113.

The first contact electrode 122a can be connected to the transistor TR through the via hole 112a provided in the first insulation layer 112. In this situation, the first contact electrode 122a can be electrically connected to a source or drain electrode of the transistor TR.

Here, a via electrode 117 of a metal material can be provided in the via hole 112a (e.g., between the transistor TR and recessed portion 113). Accordingly, the first contact electrode 122a can be in contact with the via electrode 117. For example, the via electrode 117 can be formed of tungsten (W). However, the embodiments of the present disclosure are not limited thereto. Alternatively, the via electrode 117 can be omitted, and the first contact electrode 122a can be provided in the via hole 112a and be in direct contact with the transistor TR.

In addition, a first reflection layer 122 of a metal material can be disposed in the first sub-pixel SP1 over the first insulation layer 112. The first reflection layer 122 can be located in the emission area EA of the first sub-pixel SP1. Here, a height of the first contact electrode 122a placed in the recessed portion 113 can be lower than a height of the first reflection layer 122. In the embodiments of the present disclosure, the height can be defined as a distance away from the substrate 110. Accordingly, a distance between the first contact electrode 122a placed in the recessed portion 113 and the substrate 110 can be shorter than a distance between the first reflection layer 122 and the substrate 110.

The first reflection layer 122 can be formed of the same material as the first contact electrode 122a and be in contact with the first contact electrode 122a of the first sub-pixel SP1. For example, the first reflection layer 122 and the first contact electrode 122a can be integrally formed. Accordingly, in the first sub-pixel SP1, the first reflection layer 122 can be electrically connected to the transistor TR. However, the embodiments of the present disclosure are not limited thereto. Alternatively, the first reflection layer 122 can be separated from the first contact electrode 122a.

The first reflection layer 122 and the first contact electrode 122a can be formed as a single layer or multiple layers. For example, the first reflection layer 122 and the first contact electrode 122a can be formed of aluminum (Al) or aluminum alloy, or silver (Ag) or silver alloy. The silver alloy can be silver-palladium-copper (APC). Alternatively, the first reflection layer 122 and the first contact electrode 122a can be formed as a triple-layer structure of titanium, aluminum, and titanium (Ti/Al/Ti). However, the embodiments of the present disclosure are not limited thereto.

A second insulation layer 114 can be disposed over the first reflection layer 122 and the first contact electrode 122a. The second insulation layer 114 can be disposed over a substantially entire surface of the substrate 110.

The second insulation layer 114 can be formed of an inorganic insulating material. Accordingly, the second insulation layer 114 can have a step difference due to the layers thereunder, and the step difference of the second insulation layer 114 can be located in the recessed portion 113 in a plan view. For example, second insulation layer 114 can also have a recessed portion or a depressed portion that corresponds to or overlaps with the recessed portion 113 in the first insulation layer 112. For example, the second insulation layer 114 can be formed of an inorganic insulating material such as silicon oxide (SiOx) or silicon nitride (SiNx). However, embodiments of the present disclosure are not limited thereto.

The second insulation layer 114 can have a first contact hole 114a exposing the first contact electrode 122a of each sub-pixel SP1, SP2, and SP3. That is, the first contact hole 114a can be located in the contact area CA of each sub-pixel SP1, SP2, and SP3. Here, the first contact hole 114a can be placed in or overlapping with the recessed portion 113 in a plan view. The first contact hole 114a can be spaced apart from the via hole 112a so that the via hole 112a and first contact hole 114a do not overlap with each other. However, the embodiments of the present disclosure are not limited thereto.

A second contact electrode 124a of a metal material can be disposed in each of the first, second, and third sub-pixels SP1, SP2, and SP3 over the second insulation layer 114. The second contact electrode 124a can be located in the contact area CA. Here, the second contact electrode 124a can be placed in or overlapped with the recessed portion 113 in the plan view and can overlap with the first contact electrode 122a.

The second contact electrode 124a can be connected to the first contact electrode 122a through the first contact hole 114a provided in the second insulation layer 114. Accordingly, the second contact electrode 124a can be electrically connected to the transistor TR. In this situation, the second contact electrode 124a can be in direct contact with the first contact electrode 122a.

In addition, a second reflection layer 124 of a metal material can be disposed in the second sub-pixel SP2 over the second insulation layer 114. The second reflection layer 124 can be located in the emission area EA of the second sub-pixel SP2. Here, a height of the second contact electrode 124a placed in the recessed portion 113 can be lower than a height of the second reflection layer 124. That is, a distance between the second contact electrode 124a placed in the recessed portion 113 and the substrate 110 can be shorter than a distance between the second reflection layer 124 and the substrate 110.

The second reflection layer 124 can be formed of the same material as the second contact electrode 124a and be in contact with the second contact electrode 124a of the second sub-pixel SP2. For example, the second reflection layer 124 can be integrally formed with the second contact electrode 124a. Accordingly, in the second sub-pixel SP2, the second reflection layer 124 can be electrically connected to the transistor TR. However, the embodiments of the present disclosure are not limited thereto. Alternatively, the second reflection layer 124 can be separated from the second contact electrode 124a.

The second reflection layer 124 and the second contact electrode 124a can be formed as a single layer or multiple layers. For example, the second reflection layer 124 and the second contact electrode 124a can be formed of aluminum (Al) or aluminum alloy, or silver (Ag) or silver alloy. The silver alloy can be silver-palladium-copper (APC). Alternatively, the second reflection layer 124 and the second contact electrode 124a can be formed as a triple-layer structure of titanium, aluminum, and titanium (Ti/Al/Ti). However, the embodiments of the present disclosure are not limited thereto.

A third insulation layer 116 can be disposed over the second reflection layer 124 and the second contact electrode 124a. The third insulation layer 116 can be disposed over a substantially entire surface of the substrate 110.

The third insulation layer 116 can be formed of an inorganic insulating material. Accordingly, the third insulation layer 116 can have a step difference due to the layers thereunder, and the step difference of the third insulation layer 116 can be located in the recessed portion 113 in a plan view. For example, the third insulation layer 116 can have a recessed portion that overlaps with both of a recessed portion in the second insulation layer 114 and the recessed portion 113 in the first insulation layer 112. For example, the third insulation layer 116 can be formed of an inorganic insulating material, such as silicon oxide (SiOx) or silicon nitride (SiNx). However, embodiments of the present disclosure are not limited thereto.

The third insulation layer 116 can have a second contact hole 116a exposing the second contact electrode 124a of each sub-pixel SP1, SP2, and SP3. That is, the second contact hole 116a can be located in the contact area CA of each sub-pixel SP1, SP2, and SP3. Here, the second contact hole 116a can be placed in the recessed portion 113 in a plan view. The second contact hole 116a can be spaced apart from the first contact hole 114a and the via hole 112a, so that the three different holes do not overlap with each other. Also, the first contact hole 114a can be disposed between the second contact hole 116a and the via hole 112a, in the plan view. However, the embodiments of the present disclosure are not limited thereto.

A third contact electrode 126a of a metal material can be disposed in each of the first, second, and third sub-pixels SP1, SP2, and SP3 over the third insulation layer 116. The third contact electrode 126a can be located in the contact area CA. Here, the third contact electrode 126a can be placed in the recessed portion 113 in a plan view and can overlap with the first and second contact electrodes 122a and 124a. For example, the first, second and third contact electrodes 122a, 124a and 126a can be stacked on each other.

The third contact electrode 126a can be connected to the second contact electrode 124a through the second contact hole 116a provided in the third insulation layer 116. Accordingly, the third contact electrode 126a can be electrically connected to the transistor TR. In this situation, the third contact electrode 126a can be in direct contact with the second contact electrode 124a.

In addition, a third reflection layer 126 of a metal material can be disposed in the third sub-pixel SP3 over the third insulation layer 116. The third reflection layer 126 can be located in the emission area EA of the third sub-pixel SP3. Here, a height of the third contact electrode 126a placed in the recessed portion 113 can be lower than a height of the third reflection layer 126. That is, a distance between the third contact electrode 126a placed in the recessed portion 113 and the substrate 110 can be shorter than a distance between the third reflection layer 126 and the substrate 110.

The third reflection layer 126 can be formed of the same material as the third contact electrode 126a and be in contact with the third contact electrode 126a of the third sub-pixel SP3. For example, the third reflection layer 126 can be integrally formed with the third contact electrode 126a. Accordingly, in the third sub-pixel SP3, the third reflection layer 126 can be electrically connected to the transistor TR. However, the embodiments of the present disclosure are not limited thereto. Alternatively, the third reflection layer 126 can be separated from the third contact electrode 126a.

The third reflection layer 126 and the third contact electrode 126a can be formed as a single layer or multiple layers. For example, the third reflection layer 126 and the third contact electrode 126a can be formed of aluminum (Al) or aluminum alloy, or silver (Ag) or silver alloy. The silver alloy can be silver-palladium-copper (APC). Alternatively, the third reflection layer 126 and the third contact electrode 126a can be formed as a triple-layer structure of titanium, aluminum, and titanium (Ti/Al/Ti). However, the embodiments of the present disclosure are not limited thereto.

A first electrode 120 can be provided in each of the first, second, and third sub-pixels SP1, SP2, and SP3 over the third insulation layer 116 or the third reflection layer 126. In the first and second sub-pixels SP1 and SP2, the first electrode 120 can be disposed over the third insulation layer 116 and be in contact with the third insulation layer 116. In the third sub-pixel SP3, the first electrode 120 can be disposed over the third reflection layer 126 and be in contact with the third reflection layer 126. For example, the third reflection layer 126 can be disposed between the first electrode 120 and the third insulation layer 116 in the emission area EA of the third sub-pixel SP3.

Here at least one insulation layer can be further formed between the third insulation layer 116 and the first electrode 120 and between the third reflection layer 126 and the first electrode 120.

In addition, the first electrode 120 can be extended into the contact area CA of each sub-pixel SP1, SP2, and SP3. Therefore, the first electrode 120 can be disposed over the third contact electrode 126a of each sub-pixel SP1, SP2, and SP3, and can overlap with and contact the third contact electrode 126a.

According to this, the first electrode 120 of each sub-pixel SP1, SP2, and SP3 can be electrically connected to the corresponding transistor TR through the first, second, and third contact electrodes 122a, 124a, and 126a.

The first electrode 120 can include a conductive material having relatively high work function. For example, the first electrode 120 can be formed of transparent conductive oxide (TCO) such as indium tin oxide (ITO) or indium zinc oxide (IZO).

A bank 150 can be disposed over the first electrode 120. The bank 150 can cover edges of the first electrode 120 and have an opening exposing a central portion of the first electrode 120 of each sub-pixel SP1, SP2, and SP3. A portion corresponding to the opening of the bank 150, that is, the portion of the first electrode 120 exposed by the bank 150 can be defined as the emission area EA. A remaining portion except for the emission area EA can be defined as a non-emission area. The bank 150 can be located in the non-emission area. The contact area CA can correspond to the non-emission area, and the bank 150 can be placed in the contact area CA.

For example, the bank 150 can be formed of an inorganic insulating material, such as silicon oxide (SiOx) or silicon nitride (SiNx). However, embodiments of the present disclosure are not limited thereto. Alternatively, the bank 150 can be formed of an organic insulating material such as an acrylic resin, epoxy resin, phenol resin, polyamide resin, or polyimide resin. The bank 150 can be formed as a single layer or multiple layers.

In the embodiments of the present disclosure, the bank 150 can have a flat top surface, and this will be described in detail later.

Meanwhile, a trench TCH can be formed in the bank 150 and the third insulation layer 116 between adjacent sub-pixels SP1, SP2, and SP3, that is, at a boundary of the first, second, and third sub-pixels SP1, SP2, and SP3.

In the embodiments of the present disclosure, the trench TCH can be formed in the bank 150 and the third insulation layer 116 as an example, but the embodiments of the present disclosure are not limited thereto. For example, the trench TCH can extend all the way through the bank 150 and partially through the third insulation layer 116, but embodiments are not limited thereto. Alternatively, the trench TCH can also be formed in the second insulation layer 114 or in the first and second insulation layers 112 and 114 under the third insulation layer 116.

The trench TCH can separate a light-emitting layer 130 of the adjacent sub-pixels SP1, SP2, and SP3 in a subsequent process from each other to thereby minimize a lateral leakage current. According to another embodiment, the trench TCH can pinch or thin a portion of a light-emitting layer 130 of the adjacent sub-pixels SP1, SP2, and SP3 and still minimize a lateral leakage current without fully disconnecting the light-emitting layer 130 in the areas between adjacent sub-pixels (e.g., the trench TCH can cause a portion of the light-emitting layer 130 can become very thin which increases electrical resistance).

Specifically, when the trench TCH is not formed, first and second stacks 132 and 136 and a charge generation layer 134 can be connected to each other between the adjacent sub-pixels SP1, SP2, and SP3, so that a lateral leakage current can be generated. The lateral leakage current can cause undesired sub-pixels SP1, SP2, and SP3 to emit light and decrease the color reproducibility.

The decrease in the color reproducibility can be greater when the lateral leakage current occurs between the sub-pixels emitting light of different colors than when the lateral leakage current occurs between the sub-pixels emitting light of the same color.

Accordingly, in the organic light-emitting diode display device according to the embodiment of the present disclosure, to minimize the lateral leakage current between the first, second, and third sub-pixels SP1, SP2, and SP3 emitting light of different colors, the trench TCH can be provided between the first, second, and third sub-pixels SP1, SP2, and SP3 emitting light of different colors. Here, the first stack 132 and the charge generation layer 134 between the adjacent sub-pixels SP1, SP2, and SP3 can be separated by the trench TCH, while the second stack 136 between the adjacent sub-pixels SP1, SP2, and SP3 can be connected to each other without being separated. Alternatively, the first stack 132, the charge generation layer 134, and the second stack 136 between the adjacent sub-pixels SP1, SP2, and SP3 can all be separated from each other by the trench TCH.

Meanwhile, the trench TCH may not be provided between the first, second, and third sub-pixels SP1, SP2, and SP3 emitting light of the same color, but embodiments are not limited thereto.

For example, when the organic light-emitting diode display device according to the embodiment of the present disclosure is a stripe type, as shown in FIG. 1, the first, second, and third sub-pixels SP1, SP2, and SP3 of different colors can be sequentially repeatedly arranged along the first direction, and the first sub-pixels SP1, second sub-pixels SP2, and third sub-pixels SP3 of the same color can be arranged along the second direction. In this situation, the trench TCH can be provided to have a line shape in the second direction between the sub-pixels SP1, SP2, and SP3 emitting light of different colors adjacent to each other along the first direction of FIG. 1 and may not be provided between the sub-pixels SP1, SP2, and SP3 emitting light of the same color adjacent to each other along the second direction of FIG. 1.

Next, the light-emitting layer 130 can be disposed on the first electrode 120 exposed through the opening of the bank 150 and the bank 150. The light-emitting layer 130 can include the first stack 132, the charge generation layer 134, and the second stack 136.

The first stack 132 can include at least one hole injecting layer (HIL), at least one hole transporting layer (HTL), at least one emitting material layer (EML), and at least one electron transporting layer (ETL). The emitting material layer (EML) of the first stack 132 can emit one of red light, green light, blue light, and yellow light.

The charge generation layer (CGL) 134 can include a negative type charge generation layer (N-type CGL) for providing an electron to the first stack 132 and a positive type charge generation layer (P-type CGL) for providing a hole to the second stack 136.

The second stack 136 can include at least one hole transporting layer (HTL), at least one emitting material layer (EML), at least one electron transporting layer (ETL), and at least one electron injecting layer (EIL). The emitting material layer (EML) of the second stack 136 can emit one of red light, green light, blue light, and yellow light.

Here, the emitting material layer (EML) of the second stack 136 can emit light of a different color from the emitting material layer (EML) of the first stack 132. For example, the emitting material layer (EML) of the first stack 132 can emit blue light, and the emitting material layer (EML) of the second stack 136 can emit red light and green light. Alternatively, the emitting material layer (EML) of the first stack 132 can emit blue light, and the emitting material layer (EML) of the second stack 136 can emit yellow light.

As described above, at least one including the charge generation layer 134 of the first stack 132, the charge generation layer 134, and the second stack 136 of the light-emitting layer 130 can be disconnected over the trench TCH due to a step difference of the trench TCH and be spaced apart for each of the first, second, and third sub-pixels SP1, SP2, and SP3 without contacting each other.

For example, the first stack 132 and the charge generation layer 134 can be spaced apart or disconnected for each of the first, second, and third sub-pixels SP1, SP2, and SP3. In this situation, the first stack 132 and the charge generation layer 134 can be thinner as it approaches the substrate 110 and then be cut off over the trench TCH. Meanwhile, the same materials as the first stack 132 and the charge generation layer 134 can be stacked in the trench TCH. Also, a gap space or an empty space can exist in the trench TCH in the area where the first stack 132 and the charge generation layer 134 are cut or disconnected.

As described above, in the organic light-emitting diode display device according to the embodiment of the present disclosure, the first stack 132 and the charge generation layer 134 can be separated and spaced apart for each of the first, second, and third sub-pixels SP1, SP2, and SP3 over the trench TCH, thereby minimizing the lateral leakage current between the first, second, and third sub-pixels SP1, SP2, and SP3 emitting light of different colors.

Meanwhile, in the embodiment of the present disclosure, the light-emitting layer 130 can have a two-stack structure including the first stack 132, the charge generation layer 134, and the second stack 136 as an example, but in other embodiments, the light-emitting layer 130 can have a multi-stack structure including three or more stacks and two or more charge generation layers. In this situation, two or more stacks and two or more charge generation layers can be separated by the trench TCH.

A second electrode 140 can be provided over the light-emitting layer 130. The second electrode 140 can be disposed over a substantially entire surface of the substrate 110.

The first electrode 120, the light-emitting layer 130, and the second electrode 140 can constitute the light-emitting diode De. Here, the first electrode 120 can serve as an anode, and the second electrode 140 can serve as a cathode. However, the embodiments of the present disclosure are not limited thereto. Alternatively, the first electrode 120 can serve as a cathode, and the second electrode 140 can serve as an anode.

The second electrode 140 may not be separated over the trench TCH and can be connected to each other between the first, second, and third sub-pixels SP1, SP2, and SP3. In other words, the second electrode 140 can continuously extend across the trenches TCH between the first, second, and third sub-pixels SP1, SP2, and SP3. Also, the second electrode 140 can have a depressed portion, a groove or a divot in an area overlapping with the trench TCH. Alternatively, the second electrode 140 can be separated over the trench TCH and spaced apart for each of the first, second, and third sub-pixels SP1, SP2, and SP3.

The second electrode 140 can be formed of a transparent conductive material, a semi-transmissive material, or a metal material having reflectance. The second electrode 140 can include a conductive material having relatively low work function.

For example, as stated above, when the organic light-emitting diode display device according to the embodiment of the present disclosure is a top emission type, the second electrode 140 can be formed of a transparent conductive oxide (TCO) such as indium tin oxide (ITO) or indium zinc oxide (IZO) or a semi-transmissive metal material such as magnesium (Mg), silver (Ag), or an alloy of magnesium and silver (MgAg) capable of transmitting light.

First, second, and third encapsulation layers 152, 154, and 156 can be sequentially provided over the second electrode 140. The first and third encapsulation layers 152 and 156 can be formed of an inorganic insulating material, and the second encapsulation layer 154 can be formed of an organic insulating material.

For example, the first encapsulation layer 152 can be formed of an inorganic insulating material such as aluminum oxide (AlOx), silicon oxide (SiOx), or silicon nitride (SiNx), the third encapsulation layer 156 can be formed of an inorganic insulating material such as silicon oxide (SiOx) or silicon nitride (SiNx), and the second encapsulation layer 154 can be formed of an organic insulating material such as acrylic resin or epoxy resin.

The first, second, and third encapsulation layers 152, 154, and 156 can block external moisture and oxygen.

Next, a color filter 160 can be provided over the third encapsulation layer 156. The color filter 160 can include first, second, and third color filters 160R, 160G, and 160B corresponding to the first, second, and third sub-pixels SP1, SP2, and SP3, respectively. The first, second, and third color filters 160R, 160G, and 160B can be red, green, and blue color filters, respectively. However, embodiments of the present disclosure are not limited thereto.

Also, a cover substrate or cover film can be provided over the color filter 160.

As described above, in the organic light-emitting diode display device according to an embodiment of the present disclosure, by disposing the trench TCH between the adjacent first, second, and third sub-pixels SP1, SP2, and SP3 of different colors, the first stack 132 and the charge generation layer 134 can be separated or cut in the areas between the adjacent first, second, and third sub-pixels SP1, SP2, and SP3 of different colors, thereby minimizing the lateral leakage current.

In addition, by applying a micro cavity structure to each of the first, second, and third sub-pixels SP1, SP2, and SP3, the light efficiency can be increased.

More particularly, by selectively amplifying the wavelength and emitting a narrow color spectrum using the micro cavity effect that causes light emitted from the light-emitting diode to interfere between two reflectors, light with high color purity can be obtained, and high efficiency in the front can be achieved.

To implement the micro cavity effect, distances between the two reflectors in the first, second, and third sub-pixels SP1, SP2, and SP3 can be different from each other. That is, in the organic light-emitting diode display device according to the embodiment of the present disclosure, by differing the distances between the first, second, and third reflection layers 122, 124, and 126 and the second electrode 140 from each other, the micro cavity effect can be implemented. In this situation, to adjust the distances between the first, second, and third reflection layers 122, 124, and 126 and the second electrode 140, the first, second, and third insulation layers 112, 114, and 116 can be used.

Specifically, the first reflection layer 122 of the first sub-pixel SP1 can be disposed between the first insulation layer 112 and the second insulation layer 114, the second reflection layer 124 of the second sub-pixel SP2 can be disposed between the second insulation layer 114 and the third insulation layer 116, and the third reflection layer 126 can be disposed between the third insulation layer 116 and the first electrode 120.

According to this, a second distance d2 between the second reflection layer 124 of the second sub-pixel SP2 and the second electrode 140 can be smaller than a first distance d1 between the first reflection layer 122 of the first sub-pixel SP1 and the second electrode 140 and greater than a third distance d3 between the third reflection layer 126 of the third sub-pixel SP3 and the second electrode 140 (e.g., d1>d2>d3). The first, second, and third sub-pixels SP1, SP2, and SP3 can output light having red, green, and blue main peaks corresponding to red, green, and blue colors, respectively, and intensities of the red, green, and blue main peaks can be higher than intensities of light emitted from the light-emitting layers 130 of the first, second, and third sub-pixels SP1, SP2, and SP3, respectively. Therefore, the light extraction efficiency and luminance of the red, green, and blue lights of the first, second, and third sub-pixels SP1, SP2, and SP3 can be improved.

Moreover, in the organic light-emitting diode display device according to the embodiment of the present disclosure, by providing the recessed portion 113 in the contact area CA and polishing a top surface of the bank 150 to planarize the top surface, the step difference between the contact area CA and the emission area EA can be minimized.

Specifically, since the plurality of contact electrodes 122a, 124a, and 126a and the plurality of contact holes 114a and 116a are provided in the contact area CA, the step difference of the contact area CA can be higher than that of the emission area EA and be formed at various heights. This step difference can cause the thickness of the light-emitting layer 130 to become thinner, which causes the leakage current and turns on the light-emitting diode De in an off state, resulting in panel defects.

Accordingly, in the embodiments of the present disclosure, the recessed portion 113 can be provided in the contact area CA, and the top surface of the bank 150 can be polished, so that the step difference between the contact area CA and the emission area EA can be minimized, thereby minimizing the leakage current and improving the reliability. For example, the light-emitting layer 130 can extend across the contact areas CA and the emission areas EA while maintaining a substantially same or uniform thickness and a substantially same or uniform flatness for an upper surface of the light-emitting layer 130.

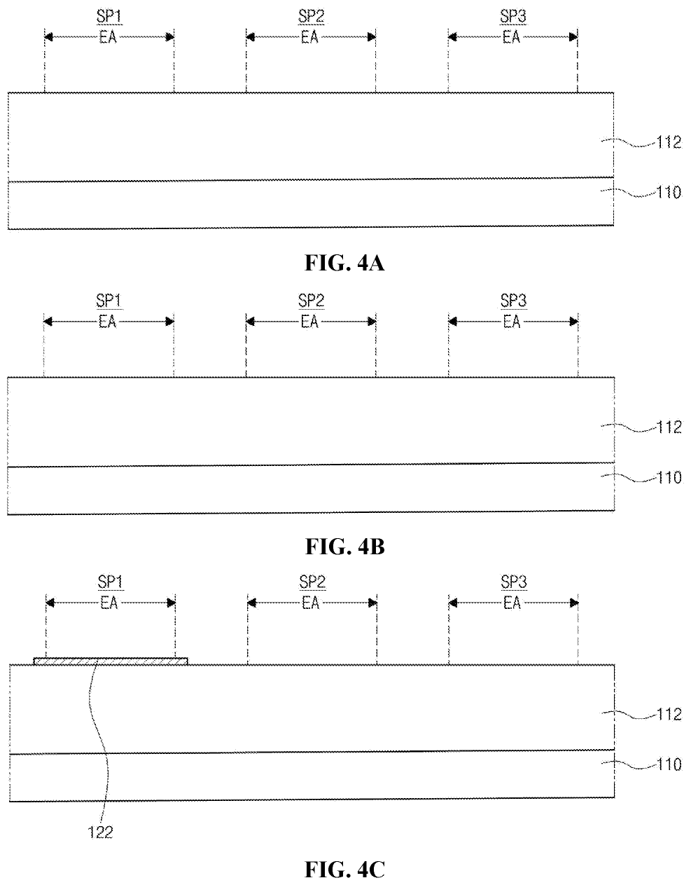

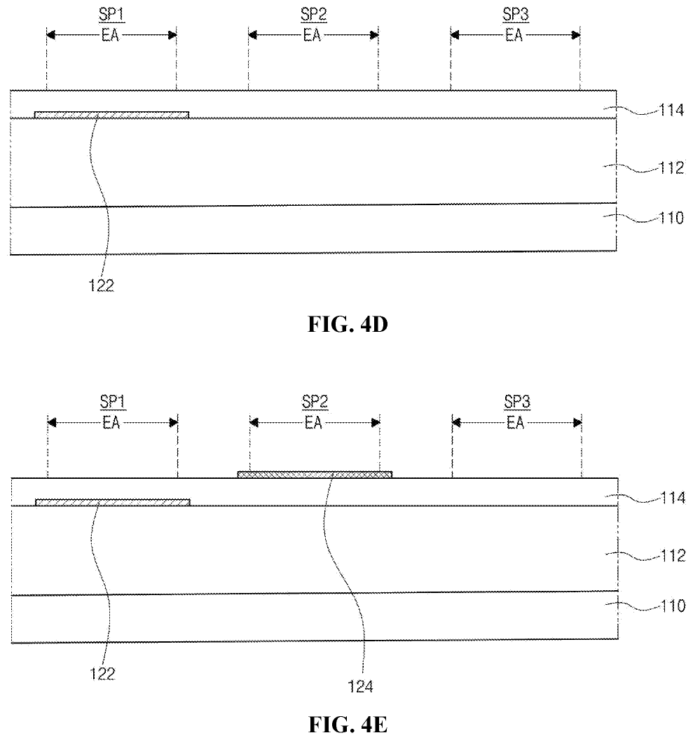

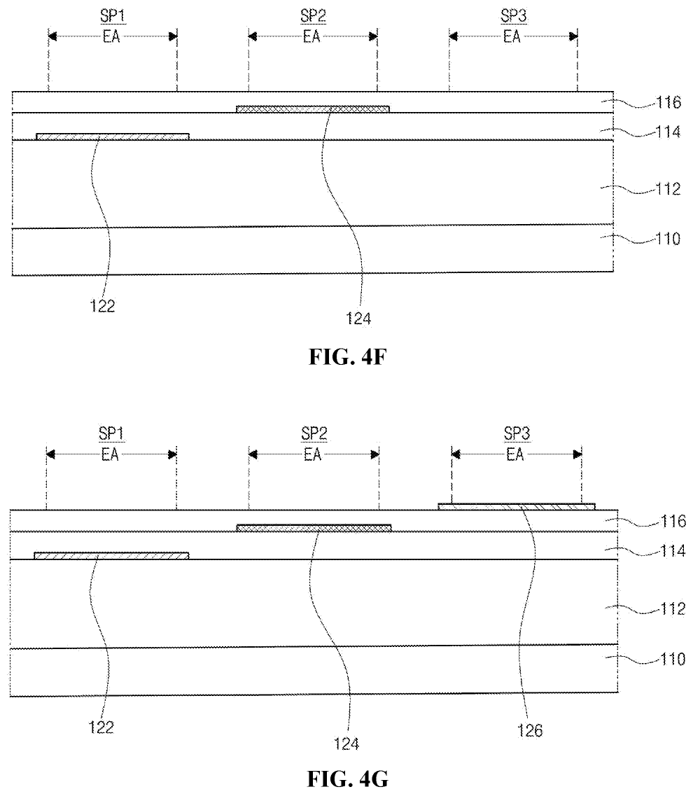

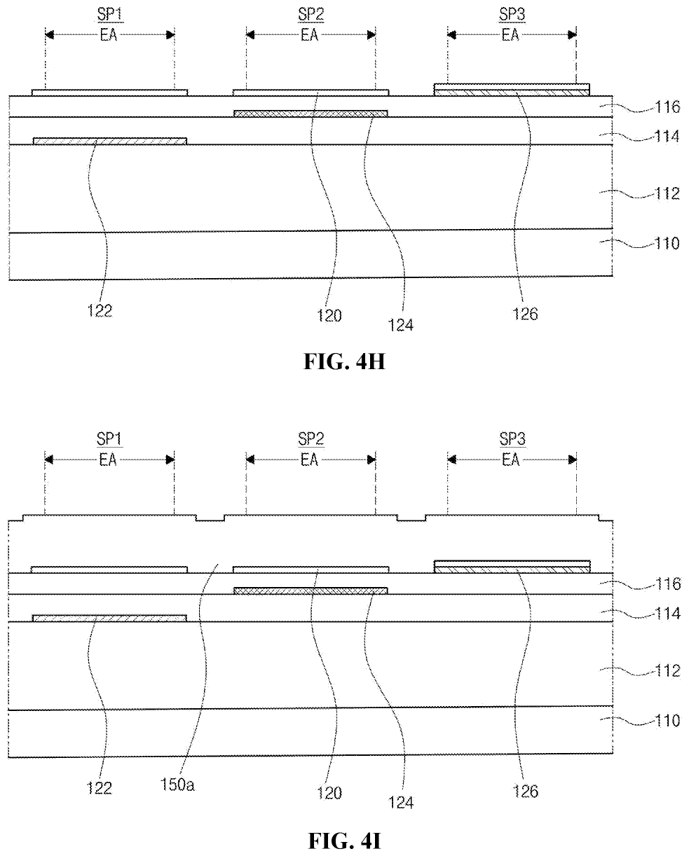

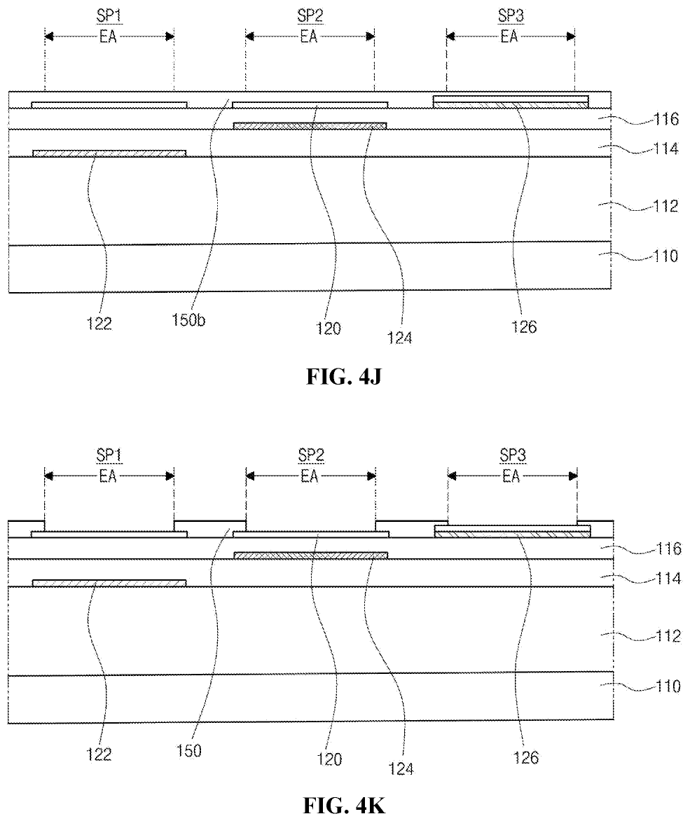

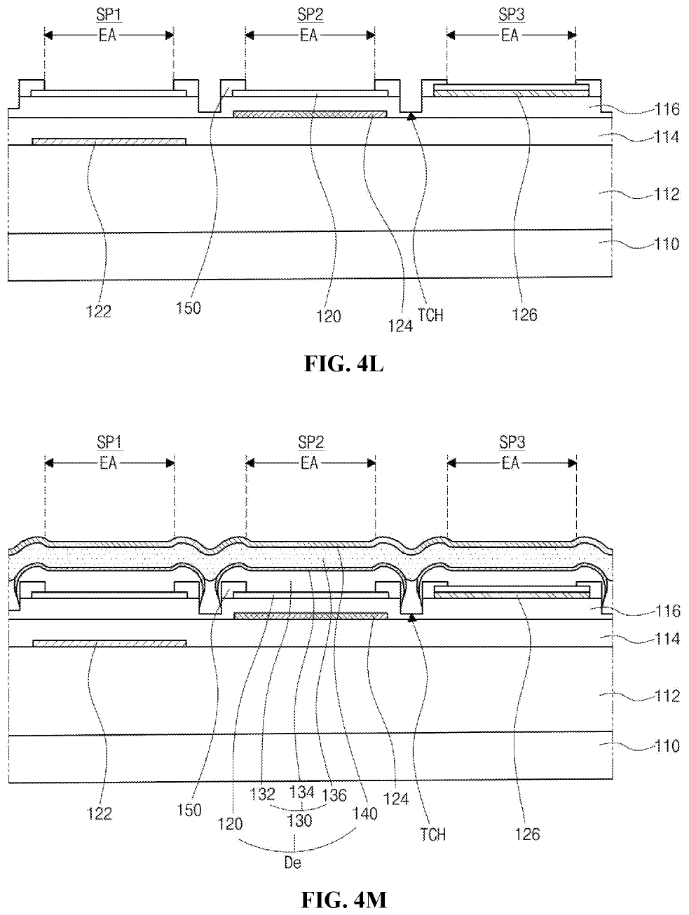

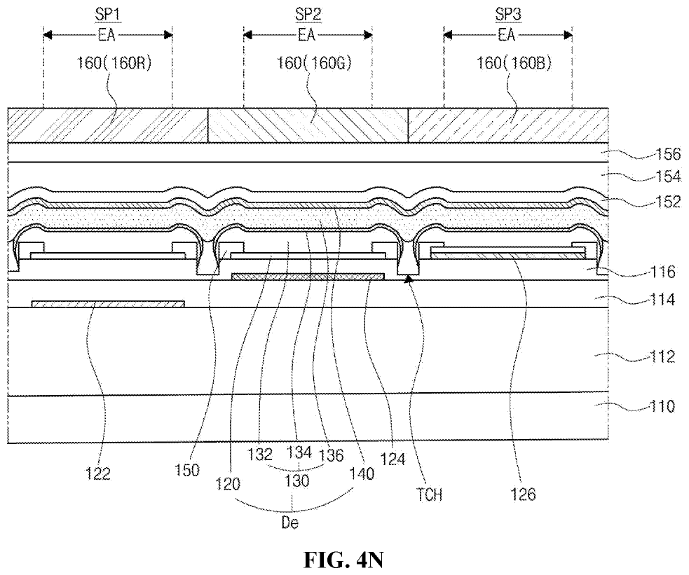

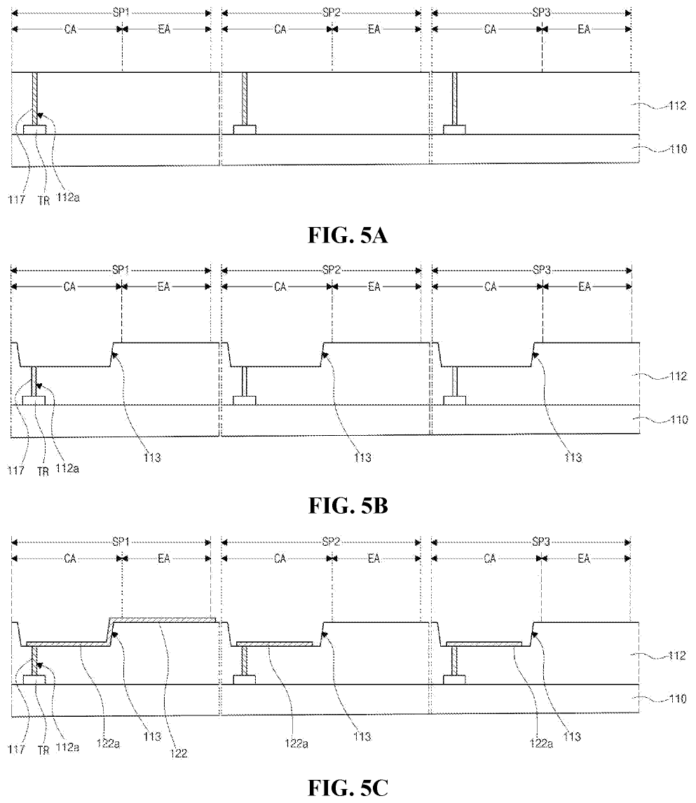

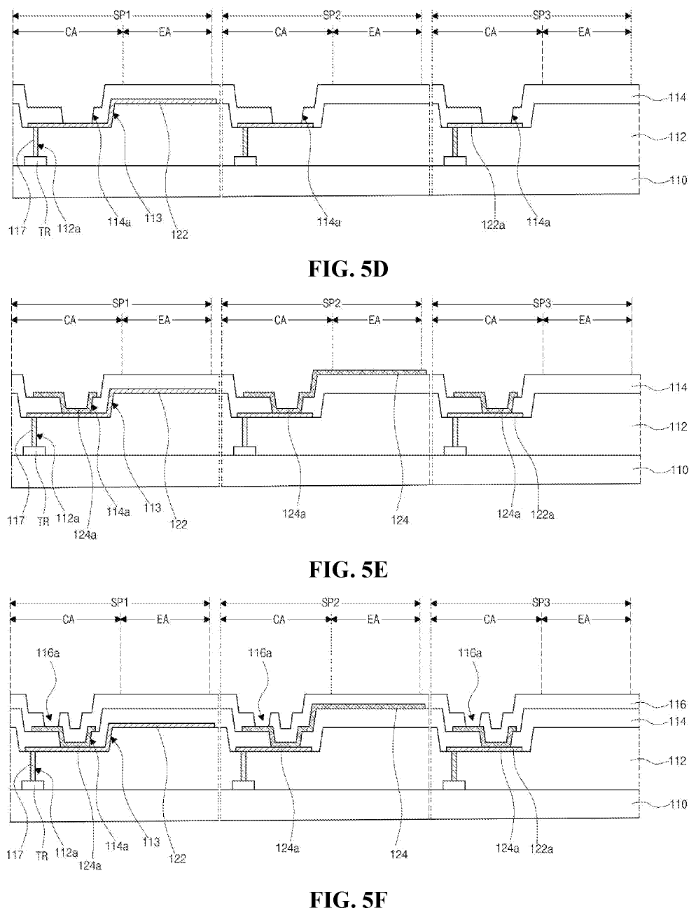

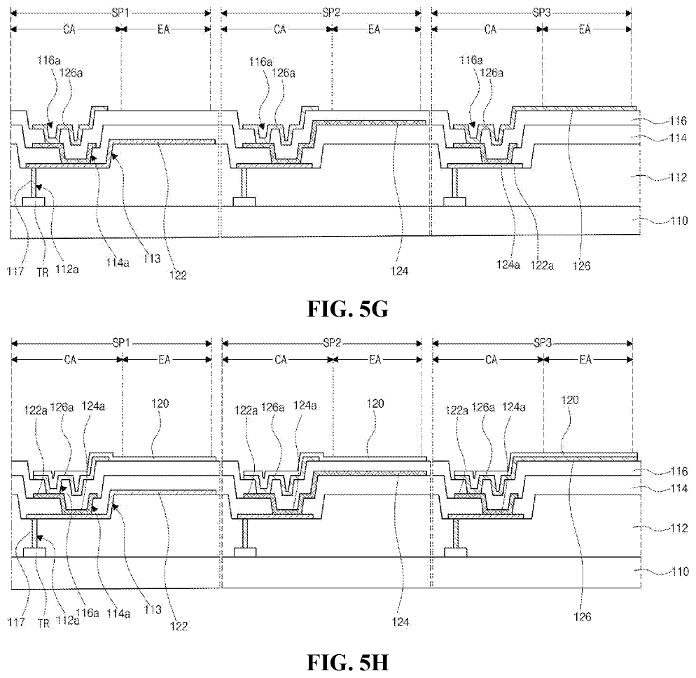

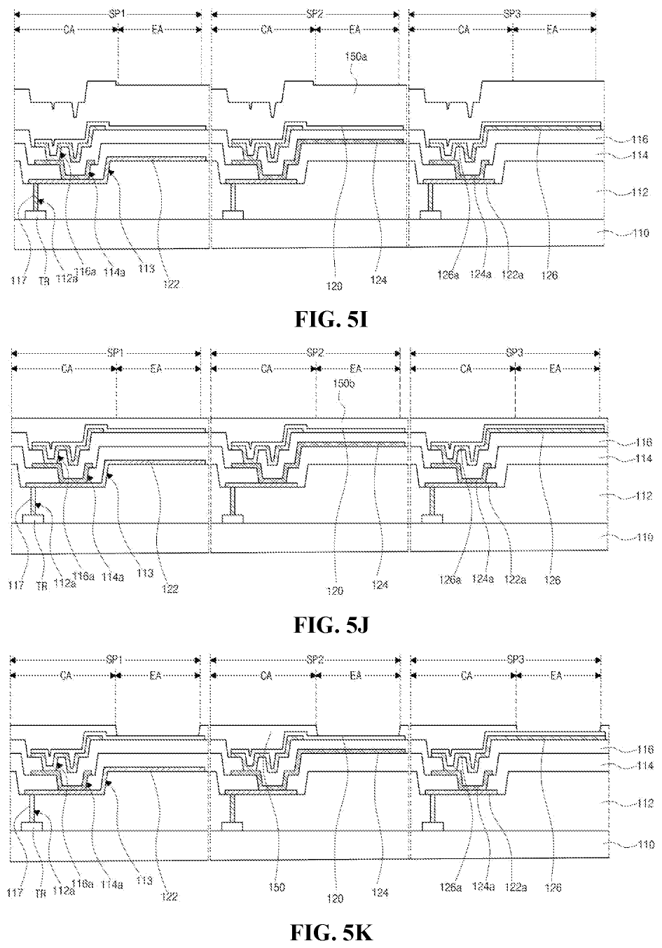

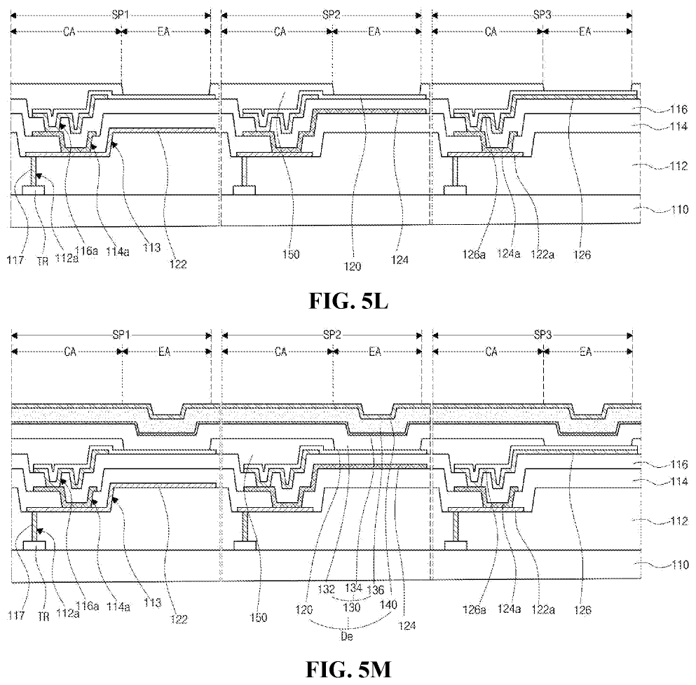

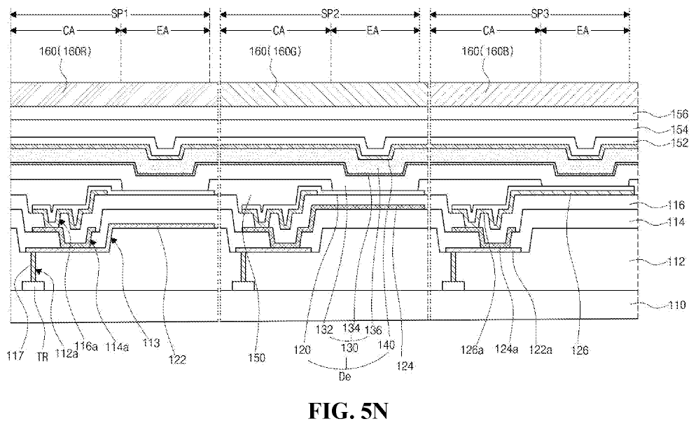

A method of manufacturing the organic light-emitting diode display device according to an embodiment of the present disclosure will be described with reference to FIGS. 4A to 4N and FIGS. 5A to 5N.

FIGS. 4A to 4N and FIGS. 5A to 5N are schematic cross-sectional views of an organic light-emitting diode display device in steps of manufacturing the organic light-emitting diode display device according to an embodiment of the present disclosure. FIGS. 4A to 4N correspond to the line I-I′ of FIG. 1, and FIGS. 5A to 5N correspond to the line II-II′, the line III-III′, and the line IV-IV′ of FIG. 1.

In FIG. 4A and FIG. 5A, the transistor TR can be formed in each of the first, second, and third sub-pixels SP1, SP2, and SP3 over the substrate 110. The transistor TR can be located in the contact area CA of each sub-pixel SP1, SP2, and SP3. However, the embodiments of the present disclosure are not limited thereto. Alternatively, the transistor TR can be placed in the emission area EA of each sub-pixel SP1, SP2, and SP3 (e.g., under the emission area EA in order to save space and reduce a footprint of each sub-pixel).

Then, the first insulation layer 112 can be formed over the substantially entire surface of the substrate 110 by depositing an insulating material over the transistor TR and can be selectively removed through a photolithography process, thereby forming the via hole 112a exposing the transistor TR.

Next, the via electrode 117 can be formed by filling the via hole 112a with a metal material. For example, the via electrode 117 can be formed of tungsten, but the embodiments of the present disclosure are not limited thereto.

Subsequently, the top surface of the first insulation layer 112 with the vial hole 112a in which the via electrode 117 is formed can be polished and flattened. Here, a chemical mechanical polishing (CMP) method using chemical and physical actions can be used for the polishing.

Next, in FIG. 4B and FIG. 5B, the recessed portion 113 can be formed by partially removing the first insulation layer 112 in the contact area CA of each sub-pixel SP1, SP2, and SP3 through a photolithography process. In this situation, the via hole 112a and the via electrode 117 can also be partially removed. According to another embodiment, the recessed portion 113 can extend all the way through first insulation layer 112 so that the transistor TR and at least a portion of the first contact electrode 122a are located on a same layer or at a same height (e.g., in this way, the via hole 112a and the via electrode 117 can be omitted), but embodiments are not limited thereto.

Next, in FIG. 4C and FIG. 5C, the first reflection layer 122 and the first contact electrode 122a can be formed by depositing a metal material over the first insulation layer 112 with the recessed portion 113 and then selectively removing the metal material through a photolithography process.

Here, the first reflection layer 122 can be disposed in the emission area EA of the first sub-pixel SP1, and the first contact electrode 122a can be disposed in the contact area CA of each sub-pixel SP1, SP2, and SP3. The first contact electrode 122a can be placed in the recessed portion 113 and be in contact with the via electrode 117. Also, the first contact electrode 122a in the first sub-pixel SP1 can have a larger size than the first contact electrode 122a in the second sub-pixel SP2 and the first contact electrode 122a in the third sub-pixel SP3. For example, the first contact electrode 122a in the first sub-pixel SP1 can be integrally formed with first reflection layer 122 which can extend into the emission area EA of the first sub-pixel SP1.

As shown in FIG. 5C, in the first sub-pixel SP1, the first reflection layer 122 and the first contact electrode 122a can be connected to each other. However, the embodiments of the present disclosure are not limited thereto. Alternatively, in other embodiments of the present disclosure, the first reflection layer 122 and the first contact electrode 122a of the first sub-pixel SP1 can be separated from and may not be electrically connected to each other.

Next, in FIG. 4D and FIG. 5D, the second insulation layer 114 can be formed over the substantially entire surface of the substrate 110 by depositing an insulating material over the first reflection layer 122 and the first contact electrode 122a and can be selectively removed through a photolithography process, thereby forming the first contact hole 114a in each sub-pixel SP1, SP2, and SP3.

The first contact hole 114a can be located in the contact area CA and can partially expose the top surface of the first contact electrode 122a. The first contact hole 114a can be placed in the recessed portion 113 in a plan view and be spaced apart from the via hole 112a.

Next, in FIG. 4E and FIG. 5E, the second reflection layer 124 and the second contact electrode 124a can be formed by depositing a metal material over the second insulation layer 114 with the first contact hole 114a and then selectively removing the metal material through a photolithography process.

Here, the second reflection layer 124 can be disposed in the emission area EA of the second sub-pixel SP2, and the second contact electrode 124a can be disposed in the contact area CA of each sub-pixel SP1, SP2, and SP3. In the contact area CA of each sub-pixel SP1, SP2, and SP3, the second contact electrode 124a can be placed in the recessed portion 113 and overlap with the first contact electrode 122a. The second contact electrode 124a can be in contact with the first contact electrode 122a through the first contact hole 114a.

As shown in FIG. 5E, in the second sub-pixel SP2, the second reflection layer 124 and the second contact electrode 124a can be connected to each other or integrally formed. However, the embodiments of the present disclosure are not limited thereto. Alternatively, in other embodiments of the present disclosure, the second reflection layer 124 and the second contact electrode 124a of the second sub-pixel SP2 can be separated from and may not be electrically connected to each other.

Next, in FIG. 4F and FIG. 5F, the third insulation layer 116 can be formed over the substantially entire surface of the substrate 110 by depositing an insulating material over the second reflection layer 124 and the second contact electrode 124a and can be selectively removed through a photolithography process, thereby forming the second contact hole 116a in each sub-pixel SP1, SP2, and SP3.

The second contact hole 116a can be located in the contact area CA and can partially expose the top surface of the second contact electrode 124a. The second contact hole 116a can be placed in the recessed portion 113 in a plan view and be spaced apart from the first contact hole 114a.

Next, in FIG. 4G and FIG. 5G, the third reflection layer 126 and the third contact electrode 126a can be formed by depositing a metal material over the third insulation layer 116 with the second contact hole 116a and then selectively removing the metal material through a photolithography process.

Here, the third reflection layer 126 can be disposed in the emission area EA of the third sub-pixel SP3, and the third contact electrode 126a can be disposed in the contact area CA of each sub-pixel SP1, SP2, and SP3. In the contact area CA of each sub-pixel SP1, SP2, and SP3, the third contact electrode 126a can be placed in the recessed portion 113 and overlap the first and second contact electrodes 122a and 124a. The third contact electrode 126a can be in contact with the second contact electrode 124a through the second contact hole 116a.

As shown in FIG. 5G, in the third sub-pixel SP3, the third reflection layer 126 and the third contact electrode 126a can be connected to each other and integrally formed. However, the embodiments of the present disclosure are not limited thereto. Alternatively, in other embodiments of the present disclosure, the third reflection layer 126 and the third contact electrode 126a of the third sub-pixel SP3 can be separated from and may not be electrically connected to each other.

Next, in FIG. 4H and FIG. 5H, the first electrode 120 can be formed in each sub-pixel SP1, SP2, and SP3 by depositing a conductive material over the third reflection layer 126 and the third contact electrode 126a and then selectively removing the conductive material through a photolithography process.

The first electrode 120 can be disposed in the emission area EA and the contact area CA of each sub-pixel SP1, SP2, and SP3. Here, the height of the first electrode 120 placed in the contact area CA can be lower than the height of the first electrode 120 placed in the emission area EA. That is, the distance between the first electrode 120 and the substrate 110 in the contact area CA can be shorter than the distance between the first electrode 120 and the substrate 110 in the emission area EA.

In the emission area EA of each of the first and second sub-pixels SP1 and SP2, the first electrode 120 can be in contact with the third insulation layer 116, and in the emission area EA of the third sub-pixel SP3, the first electrode 120 can be in contact with the third reflection layer 126. Additionally, in the contact area CA of each sub-pixel SP1, SP2, and SP3, the first electrode 120 can overlap the first, second, and third contact electrodes 122a, 124a, and 126a and can cover and contact the third contact electrode 126a. Accordingly, the first electrode 120 can be electrically connected to the corresponding transistor TR.

Next, in FIG. 4I and FIG. 5I, a bank material layer 150a can be formed over the substantially entire surface of the substrate 110 by depositing an insulating material over the first electrode 120. Here, the top surface of the bank material layer 150a may not be flat. That is, the bank material layer 150a can have step differences of various heights at the top surface thereof due to the first, second, and third contact electrodes 122a, 124a, and 126a and the first and second contact holes 114a and 116a, and thus the top surface of the bank material layer 150a can have unevenness.

The bank material layer 150a can be formed of an inorganic insulating material such as silicon oxide (SiOx) or silicon nitride (SiNx). However, the embodiments of the present disclosure are not limited thereto.

Then, in FIG. 4J and FIG. 5J, the top surface of the bank material layer 150a can be polished and planarized. In this situation, the chemical mechanical polishing (CMP) method can be used for polishing the top surface of the bank material layer 150a. Accordingly, the bank layer 150b, which has a smaller height and thickness than the bank material layer 150a and has the flat top surface, can be formed.

Next, in FIG. 4K and FIG. 5K, the bank 150 can be formed by selectively removing the bank layer 150b through a photolithography process. The bank 150 can cover the edges of the first electrode 120 and expose the central portion of the first electrode 120. The bank 150 can cover the first electrode 120 in the contact area CA and expose the first electrode 120 in the emission area EA.

The bank 150 can have the flat top surface, and the step difference between the bank 150 of the contact area CA and the first electrode 120 in the emission area EA can be relatively small. That is, the distance between the top surface of the bank 150 of the contact area CA and the top surface of the first electrode 120 of the emission area EA can be relatively small, which can allow for a thinner device.

Next, in FIG. 4L and FIG. 5L, the trench TCH can be formed by etching the bank 150 and the third insulation layer 116 at the boundary between adjacent ones of the first, second, and third sub-pixels SP1, SP2, and SP3.

Next, in FIG. 4M and FIG. 5M, the first stack 132 and the charge generation layer 134 can be sequentially formed over the first electrode 120 exposed through the opening of the bank 150 and the bank 150. The first stack 132 and the charge generation layer 134 can be formed through a thermal evaporation process. However, embodiments of the present disclosure are not limited thereto.

The first stack 132 can be separated or cut in areas between the sub-pixels SP1, SP2, and SP3 by the trench TCH. That is, the first stack 132 can be formed in an independent pattern from each other for each sub-pixel SP1, SP2, and SP3. Similarly, the charge generation layer 134 can be separated or cut in areas between the sub-pixels SP1, SP2, and SP3 by the trench TCH. That is, the charge generation layer 134 can be formed in an independent pattern from each other for each sub-pixel SP1, SP2, and SP3. Accordingly, the first stack 132 and the charge generation layer 134 of the adjacent sub-pixels SP1, SP2, and SP3 are not connected to each other, and the first stack 132 and the charge generation layer 134 can be separated for each of the sub-pixels SP1, SP2, and SP3. In this situation, each of the first stack 132 and the charge generation layer 134 can be formed along a side wall of the trench TCH and be thinner on the side wall of the trench TCH as it approaches the substrate 110 and then be cut off.

Then, the second stack 136 and the second electrode 140 can be sequentially formed over the charge generation layer 134. The second stack 136 and the second electrode 140 can be formed through a thermal evaporation process. However, the embodiments of the present disclosure are not limited thereto.

Here, the second stack 136 and the second electrode 140 of the adjacent sub-pixels SP1, SP2, and SP3 can be connected to each other without being separated. Alternatively, the second stack 136 and/or the second electrode 140 can be separated for each of the sub-pixels SP1, SP2, and SP3.

Next, in FIG. 4N and FIG. 5N, the first, second, and third encapsulation layers 152, 154, and 156 can be sequentially formed over the second electrode 140. In this situation, the first and third encapsulation layers 152 and 156 can be formed through a deposition process having excellent step coverage. Accordingly, the first and third encapsulation layers 152 and 156 can be formed along the steps of the layers thereunder and can have a non-flat top surface.

On the other hand, the second encapsulation layer 154 can eliminate the step difference caused by the layers thereunder and can have a substantially flat top surface. The second encapsulation layer 154 can be formed through a solution process. However, the embodiments of the present disclosure are not limited thereto. Alternatively, the second encapsulation layer 154 can be formed through a deposition process.

Then, by repeating steps of applying a color resist over the third encapsulation layer 156 and patterning it through a photolithography process, the first, second, and third color filters 160R, 160G, and 160B can be formed in the first, second, and third sub-pixels SP1, SP2, and SP3, respectively to thereby complete the color filter 160.

As described above, in the organic light-emitting diode display device according to the embodiment of the present disclosure, by forming the recessed portion 113 in the contact area CA and forming the bank 150 having the flat top surface through the chemical mechanical method, the step difference between the contact area CA and the emission area EA can be minimized. Accordingly, the leakage current can be minimized, and the reliability can be improved.

The organic light-emitting diode display device according to the embodiment of the present disclosure can be applied to a head mounted display. A head mounted display is a virtual reality (VR) or augmented reality (AR) glasses-type monitor device that is worn in the form of glasses or a helmet and focuses on a distance close to the user's eyes. It can be implemented by arranging various optical systems on the front surface of the organic light-emitting diode display device according to the embodiment of the present disclosure.

In the present disclosure, the lateral leakage current between adjacent sub-pixels can be minimized by disposing the trench between the adjacent sub-pixels of different colors. Therefore, the color reproducibility can be improved.

In addition, by applying the micro cavity structure to each sub-pixel, light with high color purity can be obtained, and high efficiency in the front can be achieved. Accordingly, it is possible to lower the power consumption through the improved efficiency, thereby reducing the power consumption.

Moreover, by providing the recessed portion in the contact area where the light-emitting diode and the transistor are electrically connected to each other and polishing the top surface of the bank, the step difference between the contact area and the emission area can be minimized, so that the leakage current can be minimized and the reliability can be improved.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. An organic light-emitting diode display device, comprising:
a plurality of sub-pixels disposed on a substrate;
at least one transistor disposed at each of the plurality sub-pixels over the substrate;
a first insulation layer disposed over the at least one transistor; and
a light-emitting diode disposed at each of the plurality of sub-pixels over the first insulation layer, the light-emitting diode including a first electrode, a light-emitting layer, and a second electrode,
wherein each of the plurality of sub-pixels includes a contact area and an emission area,
wherein the light-emitting diode is electrically connected to the at least one transistor in the contact area, and
wherein the first insulation layer includes a recessed portion in the contact area.

2. The organic light-emitting diode display device of claim 1, further comprising:
at least one contact electrode and at least one reflection layer disposed on a same layer between the first insulation layer and the light-emitting diode, the at least one contact electrode and at least one reflection layer including a same material,
wherein the at least one contact electrode is disposed in the contact area, and the at least one reflection layer is disposed in the emission area.

3. The organic light-emitting diode display device of claim 2, wherein the at least one contact electrode is disposed in the recessed portion of the first insulation layer, and
wherein a distance between the at least one contact electrode and the substrate is shorter than a distance between the at least one reflection layer and the substrate.

4. The organic light-emitting diode display device of claim 1, further comprising:
first, second, and third reflection layers disposed in the emission area between the first insulation layer and the light-emitting diode,
wherein the plurality of sub-pixels include first, second, and third sub-pixels, and
wherein the first, second, and third reflection layers are disposed in the first, second, and third sub-pixels, respectively.

5. The organic light-emitting diode display device of claim 4, wherein a distance between the second reflection layer and the second electrode in the second sub-pixel is smaller than a distance between the first reflection layer and the second electrode in the first sub-pixel, and
wherein the distance between the second reflection layer and the second electrode in the second sub-pixel is greater than a distance between the third reflection layer and the second electrode in the third sub-pixel.

6. The organic light-emitting diode display device of claim 4, further comprising:
second and third insulation layers disposed between the first insulation layer and the light-emitting diode,
wherein the first reflection layer is disposed between the first and second insulation layers in the first sub-pixel, the second reflection layer is disposed between the second and third insulation layers in the second sub-pixel, and the third reflection layer is disposed between the third insulation layer and the light-emitting diode in the third sub-pixel.

7. The organic light-emitting diode display device of claim 6, further comprising:
first, second, and third contact electrodes disposed in the contact area of each of the first, second, and third sub-pixels,
wherein the first, second, and third contact electrodes overlap with each other in the contact area and are electrically connected to each other, and
wherein the first, second, and third contact electrodes overlap with the recessed portion of the first insulation layer.

8. The organic light-emitting diode display device of claim 7, wherein the first contact electrode is disposed between the first and second insulation layers,
wherein the second contact electrode is disposed between the second and third insulation layers, and
wherein the third contact electrode is disposed between the third insulation layer and the light-emitting diode.

9. The organic light-emitting diode display device of claim 1, further comprising:
a bank disposed between the first electrode and the light-emitting layer, the bank covering edges of the first electrode and exposing a central portion of the first electrode,
wherein the bank is disposed in the contact area.

10. The organic light-emitting diode display device of claim 9, further comprising:
a trench disposed in the bank in an area between adjacent sub-pixels among the plurality of sub-pixels.

11. A method of manufacturing an organic light-emitting diode display device, the method comprising:
forming at least one transistor at each of a plurality of sub-pixels over a substrate;
forming at least one insulation layer over the at least one transistor, the at least one insulation layer including a recessed portion; and
forming a light-emitting diode at each of the plurality of sub-pixels over the at least one insulation layer, the light-emitting diode including a first electrode, a light-emitting layer, and a second electrode,
wherein each of the plurality of sub-pixels includes a contact area and an emission area,
wherein the light-emitting diode is electrically connected to the at least one transistor in the contact area, and
wherein the recessed portion of the at least one insulation layer is disposed in the contact area.

12. The method of claim 11, further comprising:
forming a bank between the first electrode and the light-emitting layer, the bank covering edges of the first electrode and exposing a central portion of the first electrode,
wherein the bank is disposed in the contact area.

13. The method of claim 12, wherein the forming the bank includes:
forming a bank material layer over the first electrode;
forming a bank layer by polishing a top surface of the bank material layer; and
selectively removing a portion of the bank layer.

14. The method of claim 11, further comprising:
forming at least one contact electrode and at least one reflection layer through a same process that is carried out between the forming the at least one insulation layer and the forming the light-emitting diode,
wherein the at least one contact electrode is disposed in the contact area, and the at least one reflection layer is disposed in the emission area.

15. The method of claim 14, wherein the at least one contact electrode is disposed in the recessed portion of the at least one insulation layer, and
wherein a distance between the at least one contact electrode and the substrate is shorter than a distance between the at least one reflection layer and the substrate.

16. A display device, comprising:
a first sub-pixel, a second sub-pixel and a third sub-pixel disposed on a substrate;
a first transistor, a second transistor and a third transistor disposed on the substrate and corresponding to the first sub-pixel, the second sub-pixel and the third sub-pixel, respectively;
a first light emitting element disposed in the first sub-pixel, a second light emitting element disposed in the second sub-pixel and a third light emitting element disposed in the third sub-pixel;
a first insulation layer disposed on the first transistor, the second transistor and the third transistor; and
a first reflection layer disposed in the first sub-pixel, a second reflection layer disposed in the second sub-pixel, and a third reflection layer disposed in the third sub-pixel,
wherein the first insulation layer includes a first-first recessed portion in the first sub-pixel, a first-second recessed portion in the second sub-pixel and a first-third recessed portion in the third sub-pixel.

17. The display device of claim 16, wherein the first reflection layer is located a first distance away from the first light emitting element, the second reflection layer is located a second distance away from the second light emitting element, and the third reflection layer is located a third distance away from the third light emitting element, and
wherein the first distance is greater than the second distance, and the second distance is greater than the third distance.

18. The display device of claim 16, wherein an upper end of the first reflection layer overlaps with the first light emitting element and a lower end of the first reflection layer overlaps with the first-first recessed portion in the first insulation layer,
wherein an upper end of the second reflection layer overlaps with the second light emitting element and a lower end of the second reflection layer overlaps with the first-second recessed portion in the first insulation layer, and
wherein an upper end of the third reflection layer overlaps with the third light emitting element and a lower end of the third reflection layer overlaps with the first-third recessed portion in the first insulation layer.

19. The display device of claim 16, wherein the first reflection layer is electrically connected to the first transistor,
wherein the second reflection layer is electrically connected to the second transistor, and
wherein the third reflection layer is electrically connected to the third transistor.

20. The display device of claim 16, further comprising:
a trench disposed between two adjacent sub-pixels among the first, second and third sub-pixels,
wherein at least one layer in two light emitting elements in the two adjacent sub-pixels is disconnected or cut in an area overlapping with the trench.

21. The display device of claim 16, further comprising:
a second insulation layer disposed on the first insulation layer; and
a third insulation layer disposed on the second insulation layer,
wherein the first reflection layer of the first sub-pixel is disposed between the first insulation layer and the second insulation layer,
wherein the second reflection layer of the second sub-pixel is disposed between the second insulation layer and the third insulation layer, and
wherein the third reflection layer of the third sub-pixel is disposed between the third insulation layer and the third light emitting element.

22. The display device of claim 21, further comprising:
a second-first recessed portion in the second insulation layer in the first sub-pixel, a second-second recessed portion in the second insulation layer in the second sub-pixel, and a second-third recessed portion in the second insulation layer in the third sub-pixel; and
a third-first recessed portion in the third insulation layer in the first sub-pixel, a third-second recessed portion in the third insulation layer in the second sub-pixel, and a third-third recessed portion in the third insulation layer in the third sub-pixel,
wherein the first-first recessed portion, the second-first recessed portion and the third-first recessed portion overlap with each other in the first sub-pixel,
wherein the first-second recessed portion, the second-second recessed portion and the third-second recessed portion overlap with each other in the second sub-pixel, and
wherein the first-third recessed portion, the second-third recessed portion and the third-third recessed portion overlap with each other in the third sub-pixel.

23. The display device of claim 16, wherein the first-first recessed portion in the first insulation layer does not overlap with a first emission area of the first light emitting element,
wherein the first-second recessed portion in the first insulation layer does not overlap with a second emission area of the second light emitting element, and
wherein the first-third recessed portion in the first insulation layer does not overlap with a third emission area of the third light emitting element.
